(19) United States
(12) Patent Application Publication
(10) Pub. No.: US 2024/0074299 A1
(43) Pub. Date: Feb. 29, 2024

(54) MANUFACTURING METHOD OF DISPLAY DEVICE

(71) Applicant: Samsung Display Co., LTD., Yongin-si (KR)

(72) Inventor: KYONGTAE YU, Yongin-si (KR)

(73) Assignee: Samsung Display Co., LTD., Yongin-si (KR)

(21) Appl. No.: 18/342,932

(22) Filed: Jun. 28, 2023

(30) Foreign Application Priority Data
Aug. 26, 2022 (KR) 10-2022-0107784

(51) Int. Cl. H10K 71/13; H10K 71/40

(52) U.S. Cl. CPC H10K 71/135; H10K 71/40

(57) ABSTRACT

A manufacturing method of a display device includes discharging an ink onto a substrate, drying the discharged ink, disposing a first heater below the substrate and disposing a mask plate and a second heater above the substrate, operating both the first heater and the second heater, and reducing an operation temperature of the first heater while maintaining an operation temperature of the second heater so that the ink can be deposited on the substrate again.

### CROSS-REFERENCE TO RELATED APPLICATION

This application claims priority under 35 U.S.C. § 119 from Korean Patent Application No. 10-2022-0107784, filed in the Korean Intellectual Property Office on Aug. 26, 2022, the entire contents of which are hereby incorporated by reference in its entirety.

### BACKGROUND

### 1. Technical Field

The disclosure relates to a manufacturing method of a display device.

### 2. Description of the Related Art

A display device includes a liquid crystal display device (LCD), a plasma display panel (PDP), an organic light emitting device (OLED), a field emission display device (FED), an electrophoretic display device, and the like.

In case that the display device is formed, necessary organic layers may be respectively formed in multiple pixel areas.

The above information disclosed in this Background section is only for enhancement of understanding of the background of the invention, and therefore it may contain information that does not constitute prior art under 35 U.S.C. § 102.

### SUMMARY

Embodiments have been made in an effort to provide a manufacturing method of a display device that provides a light emitting layer having a uniform thickness throughout a display area.

A method of manufacturing a display device according to an embodiment includes: discharging an ink onto a substrate; drying the discharged ink; disposing a first heater below the substrate and disposing a mask plate and a second heater above the substrate; operating both the first heater and the second heater; and reducing an operation temperature of the first heater while maintaining an operation temperature of the second heater to redeposit the ink onto the substrate.

The discharged ink may form a light emitting layer.

The display device further comprises a bank disposed on the substrate and an opening is disposed in the bank, the ink also being disposed in the opening.

The mask plate may be disposed above the bank.

The mask plate may be disposed directly on an upper surface of the bank.

The mask plate comprises a magnet to attach to the bank.

A first light emitting layer may be formed upon the drying of the discharged ink.

The operating of both the first heater and the second heater vaporizes the first light emitting layer.

In the reducing the operation temperature of the first heater, a second light emitting layer is formed in an opening of a bank.

The manufacturing method of the display device may further include reducing an operation temperature of the second heater after the reducing of the operation temperature of the first heater.

A maximum operation temperature of the first heater and a maximum operation temperature of the second heater may be about 500° C.

The ink may include a light emitting material. A molecular weight of the light emitting material may be less than or equal to about 10,000 atomic mass units.

A method of manufacturing a display device according to another embodiment includes: discharging an ink including a light emitting material onto a substrate; drying the discharged ink; disposing a first heater below the substrate and disposing a mask plate and a second heater above the substrate; operating both the first heater and the second heater, wherein an operation temperature of the first heater is less than or equal to an operation temperature of the second heater; and reducing an operation temperature of the first heater. A molecular weight of the light emitting material may be less than or equal to about 10,000 atomic mass units.

The display device further comprises a bank disposed on the substrate, the bank including an opening disposed therein, wherein the ink is discharged in the opening.

The mask plate may be disposed directly above an upper surface of the bank to block an upper side of the opening.

The drying of the discharged ink forms a first light-emitting layer comprising the light emitting material.

The operating of both the first heater and the second heater vaporizes the light emitting material.

The reducing the operation temperature of the first heater forms a second light emitting layer in the opening from the vaporized light emitting material.

In the reducing the operation temperature of the first heater, the operation temperature of the second heater may be maintained to prevent the light emitting material from being deposited onto the mask plate.

According to the embodiments, a display device including the light emitting layer of uniform thickness over an entire display area is manufactured.

### BRIEF DESCRIPTION OF THE DRAWINGS

An additional appreciation according to the embodiments of the disclosure will become more apparent by describing in detail the embodiments thereof with reference to the accompanying drawings, wherein:

FIG. 1 is a flowchart according to a method of manufacturing a display device according to an embodiment;

FIGS. 2-7 are schematic cross-sectional views of a display device according to the manufacturing method; and

FIG. 8 is a schematic cross-sectional view of a display device manufactured by the manufacturing method according to the embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing exemplary features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

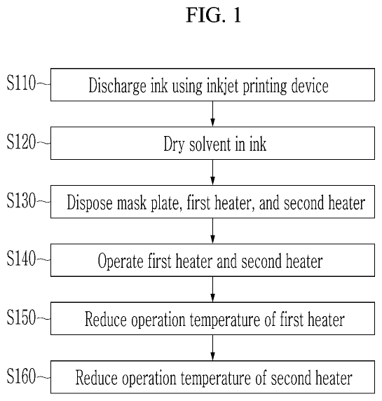

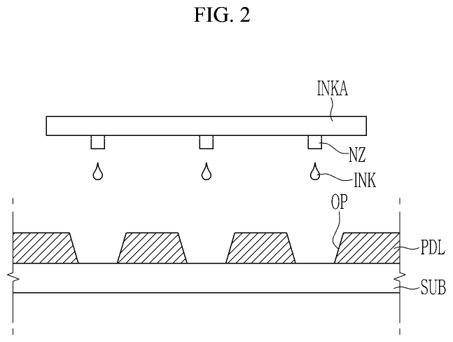

Hereinafter, a method of manufacturing a display device according to an embodiment will be described with reference to FIGS. 1-7. FIG. 1 is a flowchart according to a manufacturing method of a display device according to an embodiment, and FIGS. 2-7 are schematic cross-sectional views of a display device according to the manufacturing method.

Referring to step S110 of FIG. 1 and FIG. 2, the manufacturing method of the display device according to the embodiment may discharge an ink INK onto a substrate SUB through a nozzle NZ included in an inkjet printing device INKA. The inkjet printing device INKA may discharge the ink INK in an opening OP of a partition wall or bank PDL disposed on the substrate SUB. The opening OP of the bank PDL may overlap at least a portion of an anode described later and may define a light emitting area.

The ink INK according to an embodiment may be provided as a solution or in a colloidal state. For example, a solvent may be acetone, water, alcohol, toluene, propylene glycol (PG), propylene glycol methyl acetate (PGMA), or a combination thereof, but may not be limited thereto.

The ink INK according to an embodiment may include a light emitting material for forming a light emitting layer to be described later. The light emitting material may be a low molecular weight material (or a low molecular material). In the specification, the low molecular weight material means a molecular weight of about 10,000 atomic mass units or less.

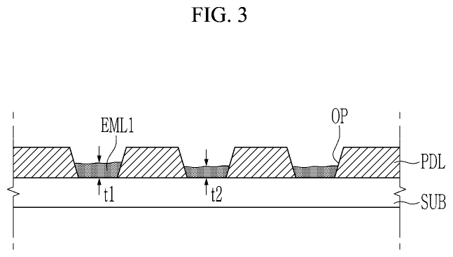

As shown in step S120 of FIG. 1, a drying process may be performed on the ink INK discharged in the opening OP of the bank PDL. According to the drying process, as shown in FIG. 3, the discharged ink (INK) may form a first light emitting layer EML1 in the opening OP. The solvent included in the ink INK may evaporate and the light emitting material may form the first light emitting layer EML1. Due to a difference in drying speed between a central portion and an outer portion of a display area, thicknesses t1 and t2 of the first light emitting layer EML1 may vary according to a position in the display area. If the thicknesses t1 and t2 of the first light emitting layer EML1 are different, a problem may occur in which luminance of an entire display device becomes non-uniform. There may be a problem that display quality of the display device may be different according to a viewing angle or a stain may be expressed.

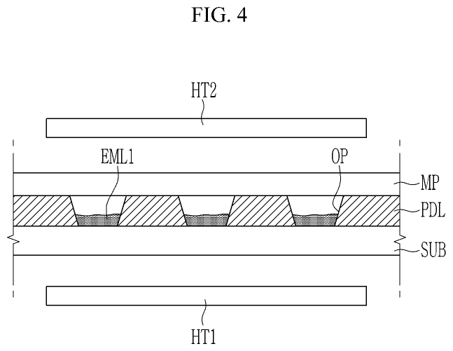

Thereafter, as shown in step S130 of FIG. 1 and FIG. 4, a first heater HT1 may be disposed under a lower surface (or a back surface) of the substrate SUB, and a second heater HT2 may be disposed above an upper surface of the substrate SUB. Further, a mask plate MP may be disposed above the substrate SUB. The mask plate MP may be disposed on the bank PDL. The mask plate MP may be disposed above (i.e., directly above) the bank PDL and may be in contact with an upper surface of the bank PDL. The mask plate MP may be in contact with the upper surface of the bank PDL in any way to provide a sealed space within the bank PDL. For example, the mask plate MP may be disposed above (i.e., directly above) the bank PDL using a magnet.

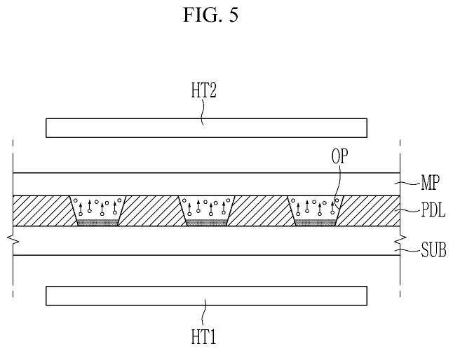

As shown in step S140 of FIG. 1 and FIG. 5, the first light emitting layer EML1 may be heated by operating both the first heater HT1 and the second heater HT2. In a step of applying heat to the first light emitting layer EML1, the light emitting material included in the first light emitting layer EML1 may be vaporized. The vaporized light emitting material may be disposed within the opening OP sealed by the mask plate MP.

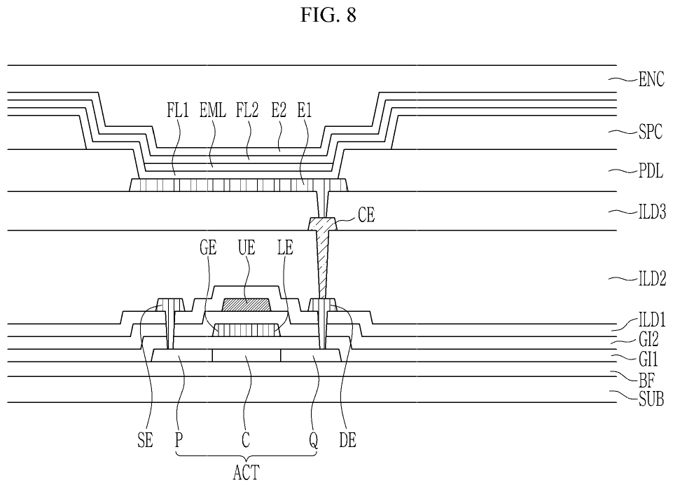

The first light emitting layer EML1 may be heated to a temperature of about 500° C. or less by both the first heater HT1 and the second heater HT2. In case that the heating temperature exceeds about 500° C., a problem may occur in which a hole transporting layer, a hole injection layer which are part of first functional layer FL1 of FIG. 8, and the like formed before the first light emitting layer EML1 are damaged.

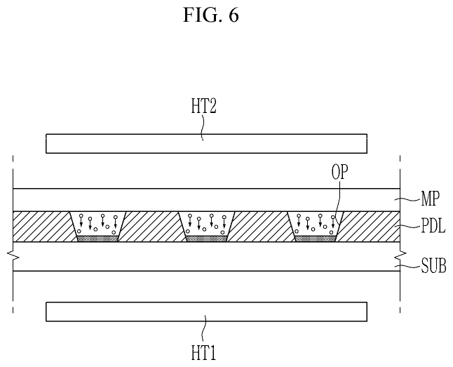

Thereafter, as shown in step S150 of FIG. 1 and FIG. 6, an operation temperature of the first heater HT1 may be reduced. As the operation temperature of the first heater HT1 decreases, an area close to the substrate SUB may be cooled. An operation temperature of the second heater HT2 may maintain the existing operation temperature so that the mask plate MP may be continuously heated. In an embodiment, an operation temperature of the first heater may be less than or equal to an operation temperature of the second heater. In the opening OP of the bank PDL, an upper side may be in a relatively heated state while a lower side may be in a relatively cooled state. The vaporized light emitting material may move again toward a lower surface of the opening OP and may be deposited in the opening OP of the bank PDL. Since the second heater HT2 continues to operate, the vaporized light emitting material may be prevented from being deposited on the mask plate MP that is heated to a relatively high temperature.

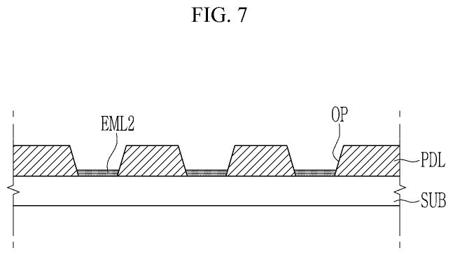

As shown in FIG. 7, the re-deposited light emitting material forms a second light emitting layer EML2. The second light emitting layer EML2 may be formed by a vaporization process and a deposition process without a solvent so that it may be provided with a uniform thickness over an entire display area. After the deposition of the light emitting material in the opening OP of the bank PDL is completed, the operation temperature of the second heater HT2 may be reduced as per step S160 of FIG. 1.

The manufacturing method of the display device according to the embodiment may vaporize the ink discharged by an inkjet process and may redeposit the vaporized ink in the opening of the bank by using the heater and the mask plate. The embodiment may provide the light emitting layer of a uniform thickness over the entire display area so that it may be possible to provide a display device with improved display quality and reliability.

Hereinafter, a display device manufactured according to the method of manufacturing the display device according to the embodiment will be described with reference to FIG. 8. FIG. 8 is a schematic cross-sectional view of the display device manufactured by the manufacturing method according to the embodiment.

Referring to FIG. 8, the display device according to the embodiment includes a substrate SUB. The substrate SUB may include an inorganic insulating material such as glass or an organic insulating material such as plastic including a polyimide (PI). The substrate SUB may be a single layer or a multilayer. The substrate SUB may have a structure in which at least one base layer including sequentially stacked polymer resins and at least one inorganic layer are alternately stacked. The substrate SUB according to an embodiment may have a structure including two base layers and an inorganic layer disposed between the two base layers.

The substrate SUB may have various degrees of flexibility. The substrate SUB may be a rigid substrate or a flexible substrate capable of bending, folding, rolling, etc.

A buffer layer BF may be disposed on the substrate SUB. The buffer layer BF may block transfer of impurities from the substrate SUB to a layer above the buffer layer BF, especially a semiconductor layer ACT, so that the buffer layer prevents degradation of the semiconductor layer ACT and reduces stress of the semiconductor layer. The buffer layer BF may include an inorganic insulating material such as a silicon nitride, a silicon oxide, an organic insulating material, or a combination thereof. Some or all of the buffer layer BF may be omitted.

The semiconductor layer ACT may be disposed on the buffer layer BF. The semiconductor layer ACT may include at least one of a polysilicon and an oxide semiconductor. The semiconductor layer ACT includes a channel region C, a first region P, and a second region Q. The first region P and the second region Q are disposed on both sides of the channel region C. The channel region C may include a semiconductor doped with a small amount of impurities or be undoped with impurities, and the first region P and the second region Q may include a semiconductor doped with a large amount of impurities compared to the channel region C. The semiconductor layer ACT may include an oxide semiconductor. A separate protective layer (not shown) may be added to protect the oxide semiconductor material that may be vulnerable to external conditions such as high temperature.

A first gate insulating layer GI1 may be disposed on the semiconductor layer ACT. The first gate insulating layer GI1 may be a single layer or a multilayer including at least one of a silicon oxide (SiOₓ), a silicon nitride (SiNₓ), and a silicon oxynitride (SiOₓN_{y}).

A gate electrode GE and a lower electrode LE are disposed on the first gate insulating layer GI1. The gate electrode GE and the lower electrode LE may be integral with each other. The gate electrode GE or the lower electrode LE may be a single layer or a multilayer in which a metal film including any one of copper (Cu), a copper alloy, aluminum (Al), an aluminum alloy, molybdenum (Mo), a molybdenum alloy, titanium (Ti), a titanium alloy, or a combination thereof may be stacked. The gate electrode GE may overlap the channel region C of the semiconductor layer ACT.

A second gate insulating layer GI2 and an upper electrode UE may be disposed above the gate electrode GE, the lower electrode LE, and the first gate insulating layer GI1. The upper electrode UE may form a capacitor with the lower electrode LE.

A first insulating layer ILD1 may be disposed on the upper electrode UE. The first insulating layer ILD1 may be a single layer or a multilayer including at least one of a silicon oxide (SiOₓ), a silicon nitride (SiNₓ), and a silicon oxynitride (SiOₓN_{y}).

A source electrode SE and a drain electrode DE are disposed on the first insulating layer ILD1. The source electrode SE and the drain electrode DE are respectively electrically connected to the first region P and the second region Q of the semiconductor layer ACT through contact holes formed in the first insulating layer ILD1.

The source electrode SE or the drain electrode DE may include aluminum (Al), silver (Ag), magnesium (Mg), gold (Au), nickel (Ni), chromium (Cr), nickel (Ni), calcium (Ca), molybdenum (Mo), titanium (Ti), tungsten (W), copper (Cu), or a combination thereof and may have a single-layer structure or a multi-layer structure including aluminum (Al), silver (Ag), magnesium (Mg), gold (Au), nickel (Ni), chromium (Cr), nickel (Ni), calcium (Ca), molybdenum (Mo), titanium (Ti), tungsten (W), copper (Cu), or a combination thereof.

A second insulating layer ILD2 may be disposed on the first insulating layer ILD1, the source electrode SE, and the drain electrode DE. The second insulating layer ILD2 may include an organic insulating material such as a general-purpose polymer such as poly(methyl methacrylate) (PMMA) or polystyrene (PS), a polymer derivative having a phenol-based group, an acryl-based polymer, an imide-based polymer, a polyimide, an acrylic polymer, a siloxane-based polymer, the like, or a combination thereof. Although the specification illustrates the second insulating layer ILD2 formed as a single layer, it may not be limited thereto, and the second insulating layer may instead be formed as multiple layers.

A connection electrode CE may be disposed on the second insulating layer ILD2. The connection electrode CE may be omitted according to an embodiment. The connection electrode CE may include aluminum (Al), silver (Ag), magnesium (Mg), gold (Au), nickel (Ni), chromium (Cr), nickel (Ni), calcium (Ca), molybdenum (Mo), titanium (Ti), tungsten (W), copper (Cu), or a combination thereof and may have a single-layer structure or a multi-layer structure including aluminum (Al), silver (Ag), magnesium (Mg), gold (Au), nickel (Ni), chromium (Cr), nickel (Ni), calcium (Ca), molybdenum (Mo), titanium (Ti), tungsten (W), copper (Cu), or a combination thereof.

A third insulating layer ILD3 and a first electrode E1 are disposed above the second insulating layer ILD2. The first electrode E1 may be electrically connected to the connection electrode CE through a contact hole of the third insulating layer ILD3, and may be electrically connected to the drain electrode DE.

The first electrode E1 may include a metal such as silver (Ag), lithium (Li), calcium (Ca), aluminum (Al), magnesium (Mg), gold (Au), or a combination thereof and may also include a transparent conductive oxide (TCO) such as indium tin oxide (ITO) indium zinc oxide (IZO), or a combination thereof. The first electrode E1 may include a single layer including a metal material or a transparent conductive oxide or a multilayer including the single layer. For example, the first electrode E1 may have a triple-layer structure of indium tin oxide (ITO)/silver (Ag)/indium tin oxide (ITO).

A transistor including the gate electrode GE, the semiconductor layer ACT, the source electrode SE, and the drain electrode DE may be electrically connected to the first electrode E1 to supply a current to a light emitting diode.

A bank PDL may be disposed on the third insulating layer ILD3 and the first electrode E1. The bank PDL overlaps at least a portion of the first electrode E1 and includes an opening defining a light emitting region. The opening may have a planar shape substantially similar to that of the first electrode E1. The opening may have a planar circular shape, but may not be limited thereto, and may have any shape such as a rhombus, or an octagonal shape, a quadrangular shape, a polygonal shape or an oval shape similar to the rhombus.

The bank PDL may include an organic material. In another example, the bank PDL may include an inorganic insulating material such as a silicon nitride, a silicon oxynitride, a silicon oxide, or a combination thereof. In yet another example, the bank PDL may include an organic material and an inorganic material. In an embodiment, the bank PDL includes a light blocking material and may be provided in black. The light blocking material may include a resin or a paste including carbon black, carbon nanotubes, or a black dye, or metal particles such as nickel, aluminum, molybdenum, an alloy of the nickel, the aluminum, and the molybdenum, metal oxide particles (e.g., chromium oxide), metal nitride particles (e.g., chromium nitride), or a combination thereof. In case that the bank PDL includes the light blocking material, reflection of external light due to metal structures disposed at a lower portion of the bank PDL may be reduced. However, the invention may not be limited thereto. In an embodiment, the bank PDL may include a translucent organic material without including the light blocking material.

A spacer SPC may be disposed on the bank PDL. The spacer SPC may include an organic material such as a polyimide. In another example, the spacer SPC may include an inorganic insulating material such as a silicon nitride (SiNₓ), a silicon oxide SiO₂, or both, or may include an organic material and an inorganic insulating material.

In an embodiment, the spacer SPC may include a same material as that of the bank PDL. The bank PDL and the spacer SPC may be formed together in a mask process using a halftone mask or the like. In an embodiment, the bank PDL and the spacer SPC may include different materials.

A light emitting layer EML may be disposed above the first electrode E1. The light emitting layer EML may include an organic material and/or an inorganic material. The light emitting layer EML may generate a color of light. The light emitting layer EML may be provided by the manufacturing method of the display device described above. According to the manufacturing method of the display device described above, the light emitting layer EML may be provided with the uniform thickness over the entire display area. Here, the uniform thickness means that a thickness difference of the light emitting layer EML over the entire display area may be less than or equal to about 1%.

A first functional layer FL1 may be disposed between the light emitting layer EML and the first electrode E1, and a second functional layer FL2 may be disposed between the light emitting layer EML and a second electrode E2.

The first functional layer FL1 includes at least one of a hole injection layer (HIL) and a hole transporting layer (HTL), and the second functional layer FL2 includes at least one of an electron transporting layer (ETL) and an electron injection layer (EIL). The hole injection layer, the hole transporting layer, the electron transporting layer, and the electron injection layer may be formed of high molecular materials. Here, the high molecular material may mean a molecular weight of about 100,000 atomic mass units or more.

Each of the first functional layer FL1 and the second functional layer FL2 may be integral with each other to cover the substrate SUB as a whole. Each of the first functional layer FL1 and the second functional layer FL2 may be formed to completely cover a display area (DA) of the substrate SUB.

The second electrode E2 may be disposed above the light emitting layer EML. The second electrode E2 may include a reflective metal including calcium (Ca), barium (Ba), magnesium (Mg), aluminum (Al), silver (Ag), gold (Au), nickel (Ni), chromium (Cr), lithium (Li), molybdenum (Mo), the like, a combination thereof, a transparent conductive oxide (TCO) such as indium tin oxide (ITO), indium zinc oxide (IZO), or a combination thereof.

The first electrode E1, the light emitting layer EML, and the second electrode E2 may constitute the light emitting diode. Here, the first electrode E1 may be an anode that may be a hole injection electrode, and the second electrode E2 may be a cathode that may be an electron injection electrode. However, an embodiment may not be necessarily limited thereto, and the first electrode E1 may instead become the cathode and the second electrode E2 may instead become the anode depending on a driving method of a light emitting display device.

In case that a hole and an electron are respectively injected into the light emitting layer EML from the first electrode E1 and the second electrode E2 and an exciton that may be generated by recombining of the injected hole and the injected electron falls from an excited state to a base state, light may be emitted.

An encapsulation layer ENC may be disposed on the second electrode E2. The encapsulation layer ENC may include at least one inorganic layer and at least one organic layer, and may have a triple layer structure including a first inorganic encapsulation layer, an organic encapsulation layer, and a second inorganic encapsulation layer. The encapsulation layer ENC may protect the light emitting layer from moisture or oxygen that may be introduced from the outside. In an embodiment, the encapsulation layer ENC may include a structure in which an inorganic layer and an organic layer are sequentially stacked. Although the specification has described the embodiment including the encapsulation layer ENC, it may not be limited thereto, and the encapsulation layer may include an encapsulation substrate made of a non-bending material.

While this invention has been described in connection with what may be presently considered to be practical embodiments, it is to be understood that the invention may not be limited to the disclosed embodiments, but, on the contrary, is intended to cover various modifications and equivalent arrangements included within the spirit and scope of the appended claims.

What is claimed is:

1. A method of manufacturing a display device, comprising:
discharging an ink onto a substrate;
drying the discharged ink;
disposing a first heater below the substrate and disposing a mask plate and a second heater above the substrate;
operating both the first heater and the second heater; and
reducing an operation temperature of the first heater while maintaining an operation temperature of the second heater to redeposit the ink onto the substrate.

2. The method of claim 1, wherein the discharged ink forms a light emitting layer.

3. The method of claim 1, wherein
the display device further comprises a bank disposed on the substrate, and
an opening is disposed in the bank, the ink also being disposed in the opening.

4. The method of claim 3, wherein the mask plate is disposed above the bank.

5. The method of claim 4, wherein the mask plate is disposed directly on an upper surface of the bank.

6. The method of claim 4, wherein the mask plate comprises a magnet to attach to the bank.

7. The method of claim 1, wherein a first light emitting layer is formed upon the drying of the discharged ink.

8. The method of claim 7, wherein the operating both the first heater and the second heater vaporizes the first light emitting layer.

9. The method of claim 8, wherein the reducing the operation temperature of the first heater forms a second light emitting layer in an opening of a bank from the vaporized light emitting material.

10. The method of claim 1, further comprising reducing an operation temperature of the second heater after the reducing of the operation temperature of the first heater.

11. The method of claim 10, wherein a maximum operation temperature of the first heater and a maximum operation temperature of the second heater are about 500° C.

12. The method of claim 1, wherein the ink comprises a light emitting material, wherein a molecular weight of the light emitting material is less than or equal to about 10,000 atomic mass units.

13. A method of manufacturing a display device, comprising:
discharging an ink including a light emitting material onto a substrate;
drying the discharged ink;
disposing a first heater below the substrate and disposing a mask plate and a second heater above the substrate;
operating both the first heater and the second heater, wherein an operation temperature of the first heater is less than or equal to an operation temperature of the second heater; and
reducing an operation temperature of the first heater.

14. The method of claim 13, wherein a molecular weight of the light emitting material is less than or equal to about 10,000 atomic mass units.

15. The method of claim 13, wherein the display device further comprises a bank disposed on the substrate, the bank including an opening disposed therein, wherein the ink is discharged in the opening.

16. The method of claim 15, wherein the mask plate is disposed directly above an upper surface of the bank to block an upper side of the opening.

17. The method of claim 15, wherein the drying of the discharged ink forms a first light emitting layer comprising the light emitting material.

18. The method of claim 17, wherein the operating both the first heater and the second heater vaporizes the light emitting material.

19. The method of claim 18, wherein the reducing the operation temperature of the first heater forms a second light emitting layer in the opening from the vaporized light emitting material.

20. The method of claim 18, wherein the reducing the operation temperature of the first heater maintains the operation temperature of the second heater to prevent the vaporized light emitting material from being deposited onto the mask plate.
